(19) United States
(12) Patent Application Publication
(10) Pub. No.: US 2025/0201558 A1
(43) Pub. Date: Jun. 19, 2025

(54) METHODS OF MANUFACTURING LOGIC DEVICES AND MEMORY DEVICES

(71) Applicant: Applied Materials, Inc., Santa Clara, CA (US)

(72) Inventors: Andrea Leoncini, Singapore (SG); Zhijie Chua, Singapore (SG); Vicknesh Sahmuganathan, Singapore (SG); Rajaram Narayanan, Milpitas, CA (US); Karthik Janakiraman, San Jose, CA (US)

(73) Assignee: Applied Materials, Inc., Santa Clara, CA (US)

(21) Appl. No.: 18/539,493

(22) Filed: Dec. 14, 2023

(51) Int. Cl. H01L 21/033

(52) U.S. Cl. CPC H01L 21/0337; H01L 21/0332

(57) ABSTRACT

Methods of manufacturing semiconductor devices, e.g., logic devices and/or memory devices, are described. Some embodiments relate to methods of depositing amorphous carbon hardmask layers that have high hardness, modulus, transparency, reduced stress, and low hydrogen content for use in logic devices and/or memory devices.

### TECHNICAL FIELD

Embodiments of the disclosure generally relate to methods for manufacturing semiconductor devices. More particular, embodiments of the disclosure are directed to methods of depositing carbon hardmask layers for semiconductor devices, such as logic devices and memory devices.

### BACKGROUND

As the semiconductor industry introduces new generations of integrated circuits (ICs) having higher performance and greater functionality, the density of the elements that form those ICs is increased, while the dimensions, size, and spacing between the individual components or elements are reduced. While in the past such reductions were limited only by the ability to define the structures using photo lithography, device geometries having dimensions measured in μm or nm have created new limiting factors, such as the conductivity of the metallic elements, the dielectric constant of the insulating material(s) used between the elements, or challenges in 3D NAND or DRAM processes. These limitations may benefit from more durable and higher hardness hardmasks.

The direct way to reduce cost per bit and increase chip density in non-volatile devices, such as 3D NAND devices, is by adding more layers. One of the critical steps in 3D NAND technology is slit etch prior to silicon nitride (SiN) recess for metal contact deposition. As the number of tiers increase in each technology node, to control the slit etch profile (uniform etching from top to bottom), the thickness of the hardmask has to be proportionally increased to withstand high aspect etch profiles. Traditionally, a very high-quality hardmask layer, which has high etch selectivity, unparalleled hardness, and high density is used.

Current hardmasks include pure or doped plasma-enhanced chemical vapor deposition (PECVD) amorphous carbon based layers due to high hardness and modulus, high transparency, and ease in removing after slit etching. Current PECVD amorphous carbon hardmask layers, however, have problems with delamination/peeling at bevel (major issue in downstream etch process), becoming more opaque with thicker layers (photo alignment issue), and poor morphology, leading to pillar striations, one sided bow, and pillar twisting. Carbon hardmask layers with high hydrogen content often show poor layer structure and intrinsic layer stress that may result in line bending or line breakage during the subsequent etching process. Current processes use small hydrocarbons, such as, for example, methane, ethane, ethylene, or acetylene, which require very precise process conditions to reduce the hydrogen content in the hardmask layers. Etch selectivity and layer density are related to low hydrogen content in the hardmask layer.

Accordingly, there is a need for hardmasks that have high hardness, modulus, transparency, but that have reduced stress and low hydrogen content.

### SUMMARY

One or more embodiments of the disclosure are directed to a method of manufacturing a semiconductor device. The method comprises exposing a semiconductor substrate in a semiconductor processing chamber to a carbon-containing precursor selected from one of more of the following compounds

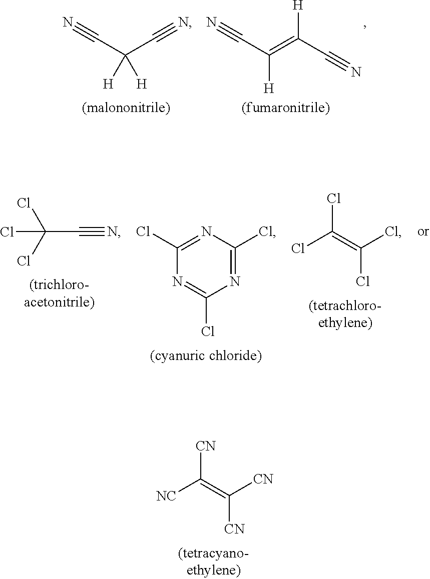

to deposit a carbon hardmask layer.

Additional embodiments of the disclosure are directed to a method of manufacturing a semiconductor device. The method comprises pre-treating a semiconductor substrate; depositing a carbon hardmask layer that is substantially free of hydrogen atoms on the semiconductor substrate by plasma-enhanced chemical vapor deposition (PECVD). In some embodiments, depositing the carbon hardmask layer comprises exposing the semiconductor substrate to a carbon-containing precursor selected from one of more of the following compounds

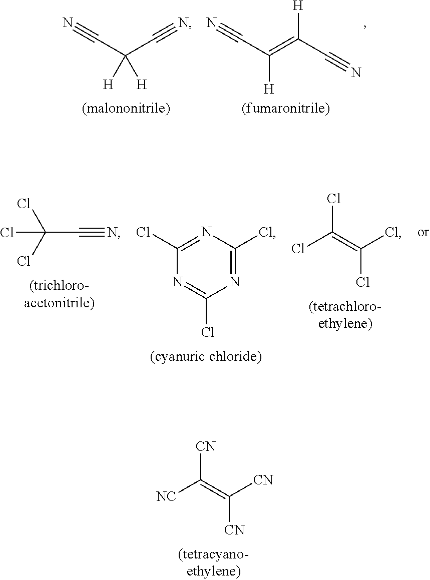

at a temperature in a range of from 100° C. to 500° C. and a pressure in a range of from 0.1 Torr to 20 Torr; and treating the carbon hardmask layer.

### BRIEF DESCRIPTION OF THE DRAWINGS

So that the manner in which the above recited features of the disclosure can be understood in detail, a more particular description of the disclosure, briefly summarized above, may be had by reference to embodiments, some of which are illustrated in the appended drawings. It is to be noted, however, that the appended drawings illustrate only typical embodiments of this disclosure and are therefore not to be considered limiting of its scope, for the disclosure may admit to other equally effective embodiments.

FIG. 1A illustrates a process flow diagram of a method of manufacturing a semiconductor device according to one or more embodiments of the disclosure;

FIG. 1B illustrates a cross-sectional schematic view of a semiconductor substrate according to one or more embodiments of the disclosure;

FIG. 1C illustrates a cross-sectional schematic view of a semiconductor substrate according to one or more embodiments of the disclosure;

FIG. 1D illustrates a cross-sectional schematic view of a semiconductor substrate according to one or more embodiments of the disclosure; and

FIG. 2 illustrates a cluster tool according to one or more embodiments of the disclosure.

### DETAILED DESCRIPTION

Before describing several exemplary embodiments of the disclosure, it is to be understood that the disclosure is not limited to the details of construction or process steps set forth in the following description. The disclosure is capable of other embodiments and of being practiced or being carried out in various ways.

The term “about” as used herein means approximately or nearly and in the context of a numerical value or range set forth means a variation of ±15%, or less, of the numerical value. For example, a value differing by ±14%, ±10%, ±5%, ±2%, or ±1%, would satisfy the definition of about.

Spatially relative terms, such as “beneath,” “below,” “lower,” “above,” “upper” and the like, may be used herein for ease of description to describe one element's relationship to another element(s) or feature(s) as illustrated in the Figures. It will be understood that the spatially relative terms are intended to encompass different orientations of the semiconductor device in use or operation in addition to the orientation depicted in the figures. For example, if the semiconductor device in the Figures is turned over, elements described as “below” or “beneath” other elements would then be oriented “above” the other elements. Thus, the exemplary term “below” may encompass both an orientation of above and below. The semiconductor device may be otherwise oriented (rotated 90 degrees or at other orientations) and the spatially relative descriptors used herein interpreted accordingly.

The use of the terms “a” and “an” and “the” and similar referents in the context of describing the materials and methods discussed herein (especially in the context of the following claims) are to be construed to cover both the singular and the plural, unless otherwise indicated herein or clearly contradicted by context. Recitation of ranges of values herein are merely intended to serve as a shorthand method of referring individually to each separate value falling within the range, unless otherwise indicated herein, and each separate value is incorporated into the specification as if it were individually recited herein. All methods described herein can be performed in any suitable order unless otherwise indicated herein or otherwise clearly contradicted by context. The use of any and all examples, or exemplary language (e.g., “such as”) provided herein, is intended merely to better illuminate the materials and methods and does not pose a limitation on the scope unless otherwise claimed. No language in the specification should be construed as indicating any non-claimed element as essential to the practice of the disclosed materials and methods.

Reference throughout this specification to “one embodiment,” “certain embodiments,” “one or more embodiments,” “some embodiments,” or “an embodiment” means that a particular feature, structure, material, or characteristic described in connection with the embodiment is included in at least one embodiment of the disclosure. Thus, the appearances of the phrases such as “in one or more embodiments,” “in certain embodiments,” “in some embodiments,” “in one embodiment,” or “in an embodiment” in various places throughout this specification are not necessarily referring to the same embodiment of the disclosure. In one or more embodiments, the particular features, structures, materials, or characteristics are combined in any suitable manner.

As used herein, the term “substrate” or “wafer” refers to a surface, or portion of a surface, upon which a process acts. It will also be understood by those skilled in the art that reference to a substrate can refer to only a portion of the substrate, unless the context clearly indicates otherwise. Additionally, reference to depositing on a substrate can mean both a bare substrate and a substrate with one or more layers or features deposited or formed thereon.

A “substrate” as used herein, refers to any substrate or material surface formed on a substrate upon which layer processing is performed during a fabrication process. For example, a substrate surface on which processing can be performed include materials such as silicon, silicon oxide, strained silicon, silicon on insulator (SOI), carbon doped silicon oxides, amorphous silicon, doped silicon, germanium, gallium arsenide, and any other materials such as metals, metal nitrides, metal alloys, and other conductive materials, depending on the application. Substrates include, without limitation, semiconductor wafers. In some embodiments, the semiconductor substrate comprises one or more of doped or undoped crystalline silicon (Si), doped or undoped crystalline silicon germanium (SiGe), doped or undoped amorphous silicon (Si), or doped or undoped amorphous silicon germanium (SiGe). Substrates may be exposed to a pretreatment process to polish, etch, reduce, oxidize, hydroxylate, anneal and/or bake the substrate surface. In addition to layer processing directly on the surface of the substrate itself, in the disclosure, any of the layer processing steps disclosed may also be performed on an under-layer formed on the substrate as disclosed in more detail below, and the term “substrate surface” is intended to include such under-layer as the context indicates. Thus, for example, where a layer/layer or partial layer/layer has been deposited onto a substrate surface, the exposed surface of the newly deposited layer/layer becomes the substrate surface.

It will be appreciated that the methods described herein can be implemented on any semiconductor substrate surface having one or more features formed therein, one or more layers formed thereon, and combinations thereof. The shape of the feature can be any suitable shape including, but not limited to, trenches, holes and vias (circular or polygonal). As used in this regard, the term “feature” refers to any intentional surface irregularity. Suitable examples of features include but are not limited to trenches, which have a top, two sidewalls and a bottom extending into the substrate, vias which have one or more sidewall extending into the substrate to a bottom, and slot vias. The features described herein can have any suitable aspect ratio (ratio of the depth of the feature to the width of the feature). In one or more embodiments, the aspect ratio of the features described herein is greater than or equal to about 1:1, 2:1, 5:1, 10:1, 15:1, 20:1, 25:1, 30:1, 35:1, or 40:1.

The term “on” indicates that there is direct contact between elements. The term “directly on” indicates that there is direct contact between elements with no intervening elements.

As used herein, the term “in situ” refers to processes that are all performed in the same processing chamber or within different processing chambers that are connected as part of an integrated processing system, such that each of the processes are performed without an intervening vacuum break. As used herein, the term “ex situ” refers to processes that are performed in at least two different processing chambers such that one or more of the processes are performed with an intervening vacuum break. In some embodiments, processes are performed without breaking vacuum or without exposure to ambient air.

As used herein, the terms “precursor,” “reactant,” “reactive gas,” “reactive species,” and the like may be used interchangeably to refer to any gaseous species that can react with a semiconductor substrate surface.

As used herein, the term “chemical vapor deposition” refers to the exposure of at least one reactive species to deposit a layer of material on the substrate surface. In some embodiments, the chemical vapor deposition (CVD) process comprises mixing the two or more reactive species in the processing chamber to allow gas phase reactions of the reactive species and deposition. In some embodiments, the CVD process comprises exposing the substrate surface to two or more reactive species simultaneously. In some embodiments, the CVD process comprises exposing the substrate surface to a first reactive species continuously with an intermittent exposure to a second reactive species. In some embodiments, the substrate surface undergoes the CVD reaction to deposit a layer having a predetermined thickness. In the CVD process, the layer can be deposited in one exposure to the mixed reactive species or can be multiple exposures to the mixed reactive species with purges between. In some embodiments, the substrate surface is exposed to the first reactive species and the second reactive species substantially simultaneously.

As used herein, “substantially simultaneously” means that most of the duration of the first reactive species exposure overlaps with the second reactive species exposure.

As used herein, the term “purging” includes any suitable purge process that removes unreacted precursor, reaction products and by-products from the process region. In one or more embodiments, purging the processing chamber includes moving the substrate through a gas curtain to a portion or sector of the processing region that contains none or substantially none of the reactant. In one or more embodiments, purging the processing chamber comprises applying a vacuum. In some embodiments, purging the processing region comprises flowing a purge gas over the substrate. In some embodiments, the purge process comprises flowing an inert gas. In one or more embodiments, the purge gas is selected from one or more of nitrogen (N₂), helium (He), and argon (Ar). In some embodiments, the first reactive species is purged from the reaction chamber for a time duration in a range of from 0.1 seconds to 30 seconds, from 0.1 seconds to 10 seconds, from 0.1 seconds to 5 seconds, from 0.5 seconds to 30 seconds, from 0.5 seconds to 10 seconds, from 0.5 seconds to 5 seconds, from 1 seconds to 30 seconds, from 1 seconds to 10 seconds, from 1 seconds to 5 seconds, from 5 seconds to 30 seconds, from 5 seconds to 10 seconds or from 10 seconds to 30 seconds before exposing the substrate to the second reactive species.

In a plasma-enhanced chemical vapor deposition (PECVD) process, for example, a carbon-containing source, such as a gas-phase carbon-containing precursor, a vapor of a liquid-phase carbon-containing precursor, or a vapor of a solid-phase carbon-containing precursor that have been entrained in a carrier gas, is introduced into a PECVD chamber. A plasma-initiated gas, such as helium (He), for example, is also introduced into the chamber. Embodiments described herein with reference to a PECVD process can be carried out using any suitable processing system. Any apparatus description described herein is illustrative and should not be construed or interpreted as limiting the scope of the embodiments described herein. The plasma may be generated by any suitable plasma source in accordance with one or more embodiments of the disclosure. For example, the plasma may be generated by a capacitively coupled plasma (CCP) source, an inductively coupled plasma (ICP) source, a microwave plasma source, or a remote plasma source.

One or more of the layers deposited on the semiconductor substrate are continuous. As used herein, the term “continuous” refers to a layer that covers an entire exposed surface without gaps or bare spots that reveal material underlying the deposited layer. A continuous layer may have gaps or bare spots with a surface area less than about 15% or less than about 10% of the total surface area of the layer.

Device manufacturers using an amorphous carbon hardmask layer demand two critical requirements be met: (1) very high selectivity of the hardmask during the dry etching of underlying materials and (2) high optical transparency in the visible spectrum for lithographic registration accuracy. As used herein, the term “dry etching” generally refers to etching processes where a material is not dissolved by immersion in a chemical solution and includes methods such as, but not limited to, reactive ion etching, sputter etching, and vapor phase etching.

Hardmasks are typically used as etch resistant layers in semiconductor processing. Ashable hardmasks have a chemical composition that allows them to be removed by a technique referred to as “ashing” once the hardmasks have served their purpose. An “ashable” hardmask is generally composed of carbon and hydrogen with trace amounts of one or more dopants (e.g., nitrogen, fluorine, boron, silicon). In a typical application, after etching, the hardmask has served its purpose and is removed. This is generally accomplished, at least in part, by ashing, also referred to as “plasma ashing” or “dry stripping.” Substrates with hardmasks to be ashed, which are generally, partially fabricated semiconductor wafers, are placed into a chamber under vacuum, and oxygen is introduced and subjected to radio frequency (RF) power, which creates oxygen radicals (plasma). The radicals react with the hardmask to oxidize it to water, carbon monoxide, and carbon dioxide. In some instances, complete removal of the hardmask may be accomplished by following the ashing with additional wet etching processes or dry etching processes, for example, when the ashable hardmask leaves behind any residue that cannot be removed by ashing alone.

Hardmask layers are often used in narrow and/or deep contact etch applications, where photoresist may not be thick enough to mask the underlying layer. This is especially applicable as the critical dimension of the feature shrinks.

In many semiconductor applications, a carbon hardmask layer is typically used in the form of an “amorphous” layer or a “nanocrystalline diamond” layer. As used herein, an “amorphous” layer refers to a layer that is formed without a crystal structure. As used herein, the term “nanocrystalline diamond” refers to a solid layer of diamond typically grown on a semiconductor substrate, such as a silicon substrate. In one or more embodiments, nanocrystallinity is the result of the enhanced re-nucleation reaction in diamond growth, where the growth of diamond crystal is disrupted due to the fluctuation of surrounding environments such as the amounts of radical species, temperature, and pressure. Nanocrystalline diamond layers are mainly comprised of small diamond crystals in nanospheres, or a nanocolumnar shape, and amorphous carbon usually distributed in the positions between surrounding crystals or accumulate in the grain boundaries. As used herein, an “amorphous” layer is not a “nanocrystalline diamond” layer and a “nanocrystalline diamond” layer is not an “amorphous” layer.

It has been found that current amorphous carbon hardmask layers have low line edge roughness, but have high hydrogen content. Carbon layers with high hydrogen content often show poor layer structure and intrinsic layer stress that may result in line bending or line breakage, both of which demonstrate poor etch resistance during a subsequent etching process. Current processes use small hydrocarbons, such as, for example, methane, ethane, ethylene, or acetylene, which require very precise process conditions to reduce the hydrogen content current amorphous carbon hardmask layers. It remains a challenge to reduce hydrogen content in current amorphous carbon hardmask layers.

Current nanocrystalline diamond layers are deposited at very high temperatures and have low hydrogen content, high density and modulus (a measurement of the mechanical strength of the layer), leading to higher etch selectivity and pattern integrity, but have high line edge roughness due to crystallinity of the layer. Layers, particularly thick layers, with high modulus have line wiggling and other issues. It has also been found that a patterned nanocrystalline diamond layer may not follow the predetermined photolithography pattern because the edges of the features will follow the boundaries of the crystals of the nanocrystalline diamond layer, resulting in jagged edges.

Embodiments of the disclosure advantageously provide methods of manufacturing semiconductor devices, e.g., logic devices and/or memory devices, that include carbon hardmask layers which meet device manufacturer critical requirements. Advantageously, embodiments of the disclosure provide carbon hardmask layers having high hardness, high modulus, and high transparency. Some embodiments advantageously provide carbon-containing precursors that have low hydrogen content for use in carbon hardmask layer deposition and semiconductor device manufacturing processes. Some embodiments advantageously provide amorphous carbon hardmask layers having low hydrogen content. Some embodiments advantageously provide amorphous carbon hardmask layers having reduced stress. Some embodiments advantageously provide ashable carbon hardmask layers.

The embodiments of the disclosure are described by way of the Figures, which illustrate semiconductor devices and methods of manufacturing semiconductor devices in accordance with one or more embodiments of the disclosure. The processes shown are merely illustrative possible uses for the disclosed processes, and the skilled artisan will recognize that the disclosed processes are not limited to the illustrated applications.

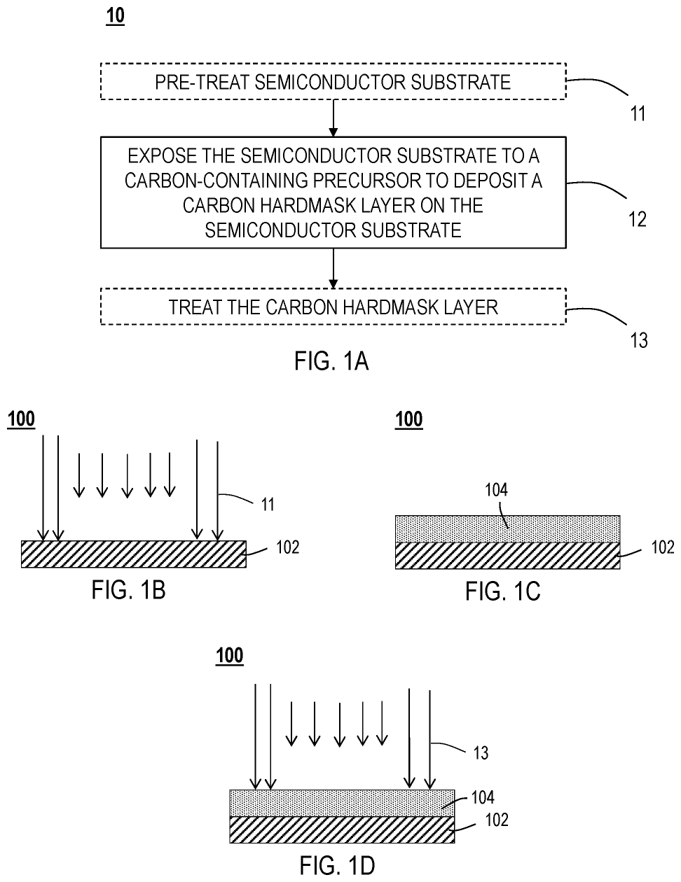

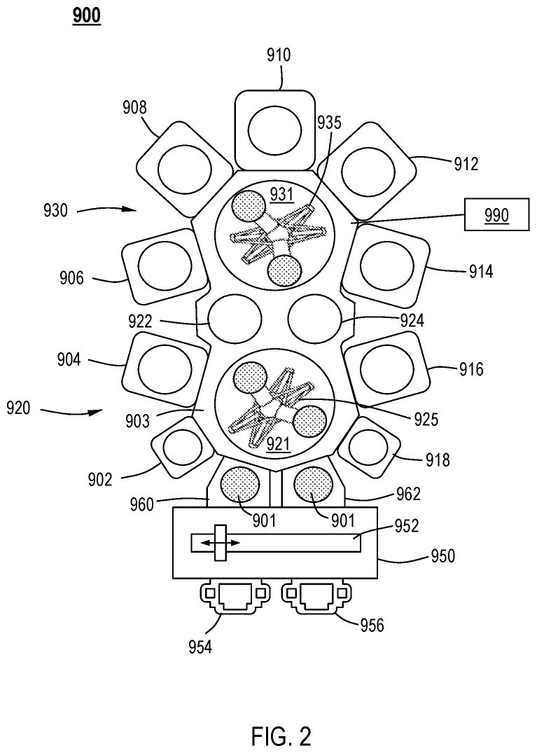

FIG. 1A illustrates a process flow diagram of a method 10 of manufacturing a semiconductor device 100 in accordance with one or more embodiments of the disclosure. FIGS. 1B-1D illustrate embodiments of the semiconductor device 100 manufactured in accordance with the method 10. FIG. 2 illustrates a cluster tool 900 in which any of the semiconductor devices described herein, e.g., semiconductor device 100, can be manufactured and any of the methods described herein e.g., method 10, can be performed.

Referring to FIGS. 1A-1D, in one or more embodiments, the method 10 comprises optionally, pre-treating a semiconductor substrate 102 (operation 11), exposing the semiconductor substrate 102 to a carbon-containing precursor selected from one of more of the following compounds

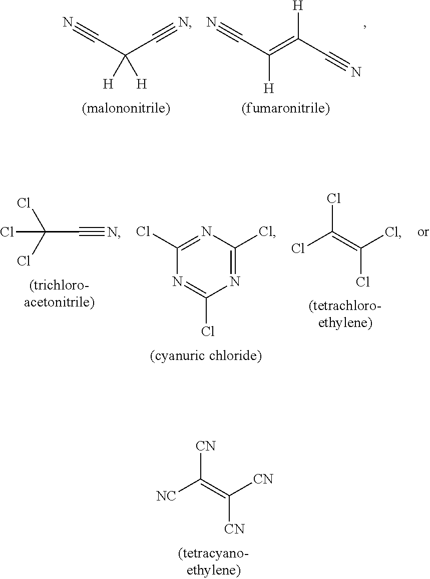

to deposit a carbon hardmask layer 104 (operation 12), and optionally, treating the carbon hardmask layer 104 (operation 13).

In some embodiments, the method 10 comprises operation 11, operation 12, and operation 13. In some embodiments, the method 10 comprises operation 11 and operation 12. In some embodiments, the method 10 comprises operation 12. In some embodiments, the method 10 consists essentially of operation 11, operation 12, and operation 13. In some embodiments, the method 10 consists essentially of operation 11 and operation 12. In some embodiments, the method 10 consists essentially of operation 12. In some embodiments, the method 10 consists of operation 11, operation 12, and operation 13. In some embodiments, the method 10 consists of operation 11 and operation 12. In some embodiments, the method 10 consists of operation 12.

FIG. 1B illustrates pre-treating the semiconductor substrate 102 according to one or more embodiments of operation 11 (denoted by arrows). The pre-treatment can be any suitable pre-treatment known to the skilled artisan. In some embodiments, pre-treating the semiconductor substrate 102 includes exposing the semiconductor substrate 102 to a plasma comprising one or more of hydrogen (H₂), carbon monoxide (CO), carbon dioxide (CO₂), argon (Ar), helium (He), diborane (B₂H₆), nitrogen (N₂), ammonia (NH₃), or a gaseous hydrocarbon. As used herein, the “gaseous hydrocarbon” may include any suitable compound that includes hydrogen atoms and carbon atoms that is introduced in a gas phase. In some embodiments, the gaseous hydrocarbon includes one or more of methane (CH₄), ethane (C₂H₆), ethylene (C₂H₄), acetylene (C₂H₂), propane (C₃H₈), propylene (C₃H₆), or butane (C₄H₁₀).

In one or more unillustrated embodiments, pre-treating the semiconductor substrate 102 includes depositing a seed layer directly on the semiconductor substrate 102. In embodiments where pre-treating the semiconductor substrate 102 includes depositing a seed layer directly on the semiconductor substrate 102, the carbon hardmask layer 104 is deposited directly on the seed layer. As used herein, the “seed layer” refers to any layer of material that promotes the growth of the carbon hardmask layer 104. The seed layer may include any suitable material that promotes the growth of the carbon hardmask layer 104. In one or more embodiments, the seed layer comprises one or more of amorphous carbon, nanocrystalline diamond, graphitic carbon, spin-on carbon, or graphene. In specific embodiments, the seed layer comprises the same material as the carbon hardmask layer 104.

FIG. 1C illustrates deposition of the carbon hardmask layer 104 according to one or more embodiments of operation 12. In embodiments where pre-treating the semiconductor substrate 102 includes depositing a seed layer directly on the semiconductor substrate 102, the carbon hardmask layer 104 is deposited directly on the seed layer. In embodiments where pre-treating the semiconductor substrate 102 does not include depositing a seed layer directly on the semiconductor substrate 102, the carbon hardmask layer 104 may be deposited directly on the semiconductor substrate 102, as shown in FIG. 1C. The semiconductor substrate 102 can include any suitable substrate material. In one or more embodiments, the semiconductor substrate 102 comprises a semiconductor material, e.g., silicon (Si), carbon (C), germanium (Ge), silicon germanium (SiGe), gallium arsenide (GaAs), indium phosphate (InP), indium gallium arsenide (InGaAs), indium aluminum arsenide (InAlAs), germanium (Ge), silicon germanium (SiGe), other semiconductor materials, or any combination thereof. In one or more embodiments, the semiconductor substrate 102 comprises one or more of silicon (Si), germanium (Ge), gallium (Ga), arsenic (As), indium (In), phosphorus (P), or selenium (Se). In some embodiments, the semiconductor substrate 102 comprises one or more of doped or undoped crystalline silicon (Si), doped or undoped crystalline silicon germanium (SiGe), doped or undoped amorphous silicon (Si), or doped or undoped amorphous silicon germanium (SiGe).

At operation 12, in one or more embodiments, the semiconductor substrate 102 is exposed to a carbon-containing precursor selected from one of more of the following compounds

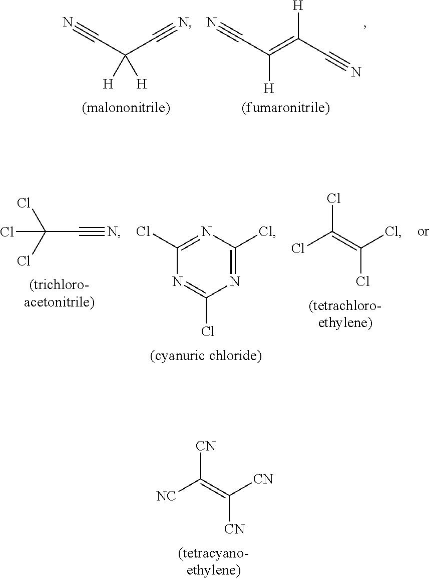

to deposit the carbon hardmask layer 104.

The carbon hardmask layer 104 may be deposited by any suitable deposition technique. In some embodiments, the carbon hardmask layer 104 is deposited by a plasma-enhanced process, such as a plasma-enhanced atomic layer deposition (PEALD) process or a plasma-enhanced chemical vapor deposition (PECVD) process. In some embodiments, the carbon hardmask layer 104 is deposited by a PECVD process. In some embodiments, the PECVD process is carried out with an inert gas. In some embodiments, the inert gas includes, but is not limited to, argon (Ar), a plasma of argon (Ar), helium (He), a plasma of helium (He), nitrogen (N₂), a plasma of nitrogen (N₂), or combinations thereof. In some embodiments, the PECVD process further comprises a plasma of one or more of hydrogen (H₂), carbon monoxide (CO), carbon dioxide (CO₂), diborane (B₂H₆), nitrogen (N₂), ammonia (NH₃), or a gaseous hydrocarbon. In some embodiments, the PECVD process is carried out with an inert gas (e.g., argon (Ar), a plasma of argon (Ar), helium (He), a plasma of helium (He), nitrogen (N₂), a plasma of nitrogen (N₂), or combinations thereof), and a plasma of one or more of hydrogen (H₂), carbon monoxide (CO), carbon dioxide (CO₂), diborane (B₂H₆), nitrogen (N₂), ammonia (NH₃), or a gaseous hydrocarbon. In one or more embodiments, the gaseous hydrocarbon includes one or more of methane (CH₄), ethane (C₂H₆), ethylene (C₂H₄), acetylene (C₂H₂), propane (C₃H₈), propylene (C₃H₆), or butane (C₄H₁₀).

The semiconductor substrate 102 can be maintained at any suitable temperature and pressure depending on, for example, the thermal budget of the semiconductor device being formed, or the reactive species being used. In some embodiments, the carbon hardmask layer is deposited at a temperature in a range of from 100° C. to 500° C., including any subranges or values therebetween. In some embodiments, the carbon hardmask layer is deposited at a pressure in a range of from 0.1 Torr to 20 Torr, including any subranges or values therebetween.

Advantageously, in one or more embodiments, the carbon hardmask layer 104 is free of or substantially free of hydrogen atoms. As used herein, the term “substantially free of” means that there is less than 5%, on an atomic basis, of hydrogen atoms present in the stated layer. As used herein, “substantially free of hydrogen atoms” corresponds to a low hydrogen content.

It has advantageously been found that the carbon hardmask layer 104 is free of or substantially free of hydrogen atoms based upon the carbon-containing precursor that is used. Advantageously, the carbon hardmask layer 104 is free of or substantially free of hydrogen atoms when the carbon-containing precursor is selected from one or more of the following compounds

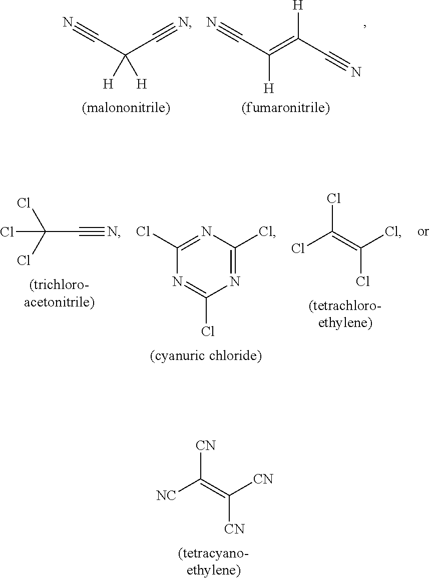

The process of operation 12 may be performed until a predetermined thickness of carbon hardmask layer 104 has been formed. In some embodiments, the thickness of the carbon hardmask layer 104 is evaluated to determine if it has reached the predetermined thickness. The predetermined thickness may vary based upon the particular application in which the carbon hardmask layer 104 is being used. In some embodiments, the carbon hardmask layer 104 has a thickness in a range of from 100 nm to 1000 nm. If the predetermined thickness has not been reached, the method 10 repeats, returning, optionally, to operation 11, and to operation 12 for further deposition. If the predetermined thickness has been reached, the method 10 moves to optional post-processing steps at operation 13, or the method 10 ends.

The optional post-processing steps of operation 13 (denoted by arrows) may be individually or collectively referred to as “treating” the carbon hardmask layer 104. In some embodiments, treating the carbon hardmask layer 104 at operation 13, includes for example, a further layer deposition process (e.g., repeating operation 12) to grow additional layers, or a process to modify the hardmask layer properties (e.g., exposing the layer to a plasma and/or annealing).

In some embodiments, treating the carbon hardmask layer 104 at operation 13 includes exposing the carbon hardmask layer 104 to a plasma comprising one or more of hydrogen (H₂), carbon monoxide (CO), carbon dioxide (CO₂), argon (Ar), helium (He), diborane (B₂H₆), nitrogen (N₂), ammonia (NH₃), or a gaseous hydrocarbon. In one or more embodiments, the gaseous hydrocarbon includes one or more of methane (CH₄), ethane (C₂H₆), ethylene (C₂H₄), acetylene (C₂H₂), propane (C₃H₈), propylene (C₃H₆), or butane (C₄H₁₀).

In some embodiments, treating the carbon hardmask layer 104 at operation 13 comprises performing an annealing process. The annealing process may include any suitable annealing process known to the skilled artisan. In some embodiments, the annealing process is performed at temperatures in the range of from 100° C. to 1100° C.

In some embodiments, the carbon hardmask layer 104 is plasma annealed. In some embodiments, the plasma anneal is any suitable type of plasma including, but not limited to, conductively coupled plasma (CCP), inductively coupled plasma (ICP), using any suitable plasma power source such as, but not limited to, radiofrequency (RF), direct current (DC), or microwave. In some embodiments, the plasma anneal comprises a plasma gas selected from one or more of nitrogen (N₂), ammonia (NH₃), or argon (Ar). In some embodiments, the plasma anneal is a CCP without argon (Ar) as the plasma species. In some embodiments, annealing the carbon hardmask layer 104 increases the density, decreases the resistivity and/or increases the purity of the layer. Any suitable power can be used depending on, for example, the precursor, the composition of the plasma, or the other process conditions. In some embodiments, the plasma is generated with a plasma power in the range of from 10 W to 3000 W.

In the embodiment illustrated in FIG. 1D, the carbon hardmask layer 104 is optionally treated after the predetermined layer thickness has been formed, though the skilled artisan will appreciate that the disclosure is not limited to such configurations. In one or more embodiments, treating the carbon hardmask layer 104 at operation is included in the deposition of the carbon hardmask layer 104 at operation 12. In specific embodiments, a portion of the carbon hardmask layer 104 may be deposited at operation 12, treated at operation 13, and another portion of the carbon hardmask layer 104 may be deposited at operation 12, treated at operation 13, and so on.

In one or more embodiments, the carbon hardmask layer 104 is ashable and is used as part of an ashing process. The skilled artisan will be able to implement appropriate functionality to the carbon hardmask layer 104 that is used as part of an ashing process based on the above description without undue experimentation.

In one or more embodiments, the semiconductor device 100 is a logic device or a memory device. In some embodiments, the semiconductor device 100 is a logic device. In some embodiments, the semiconductor device 100 is a memory device. As will be appreciated by the skilled artisan, the semiconductor device 100 (e.g., the logic device or the memory device) will include the carbon hardmask layer 104 along with any additional features or components to form the respective logic device or memory device. The skilled artisan will be able to implement appropriate functionality to a logic device or a memory device based on the above description without undue experimentation.

Additional embodiments of the disclosure are directed to cluster tools 900 for the formation of the semiconductor devices and practice of the methods described, as shown in FIG. 2. The cluster tool 900 includes at least one central transfer station 921, 931 with a plurality of sides. A robot 925, 935 is positioned within the central transfer station 921, 931 and is configured to move a robot blade and a wafer to each of the plurality of sides.

The cluster tool 900 comprises a plurality of processing chambers 902, 904, 906, 908, 910, 912, 914, 916, and 918, also referred to as process stations, connected to the central transfer station 921, 931. The various processing chambers provide separate processing regions isolated from adjacent process stations. The processing chamber can be any suitable chamber including, but not limited to, a pre-cleaning chamber, a buffer chamber, transfer space(s), a wafer orienter/degas chamber, a cryo cooling chamber, a deposition chamber, annealing chamber, etching chamber, a rapid thermal processing (RTP) chamber, a plasma oxidation chamber, a plasma nitridation chamber, an atomic layer deposition (ALD) chamber, including a plasma-enhanced ALD (PELAD) chamber, and a chemical vapor deposition (CVD) chamber, including a plasma-enhanced CVD (PECVD) chamber.

In one or more embodiments, the cluster tool 900 is an integrated system such that all of the operations of method 10 are performed in situ. In some embodiments, one or more of the operations of method 10 are performed ex situ in the cluster tool 900.

The particular arrangement of processing chambers and components can be varied depending on the cluster tool and should not be taken as limiting the scope of the disclosure. In the embodiment shown in FIG. 2, a factory interface 950 is connected to a front of the cluster tool 900. The factory interface 950 includes a loading chamber 954 and an unloading chamber 956 on a front 951 of the factory interface 950. While the loading chamber 954 is shown on the left and the unloading chamber 956 is shown on the right, those skilled in the art will understand that this is merely representative of one possible configuration.

The size and shape of the loading chamber 954 and unloading chamber 956 can vary depending on, for example, the substrates being processed in the cluster tool 900. In the embodiment shown, the loading chamber 954 and unloading chamber 956 are sized to hold a wafer cassette with a plurality of wafers positioned within the cassette.

A robot 952 is within the factory interface 950 and can move between the loading chamber 954 and the unloading chamber 956. The robot 952 is capable of transferring a wafer from a cassette in the loading chamber 954 through the factory interface 950 to load lock chamber 960. The robot 952 is also capable of transferring a wafer from the load lock chamber 962 through the factory interface 950 to a cassette in the unloading chamber 956. As will be understood by those skilled in the art, the factory interface 950 can have more than one robot 952. For example, the factory interface 950 may have a first robot that transfers wafers between the loading chamber 954 and load lock chamber 960, and a second robot that transfers wafers between the load lock 962 and the unloading chamber 956.

The cluster tool 900 shown has a first section 920 and a second section 930. The first section 920 is connected to the factory interface 950 through load lock chambers 960, 962. The first section 920 includes a first transfer chamber 921 with at least one robot 925 positioned therein. The robot 925 is also referred to as a robotic wafer transport mechanism. The first transfer chamber 921 is centrally located with respect to the load lock chambers 960, 962, process chambers 902, 904, 916, 918, and buffer chambers 922, 924. The robot 925 of some embodiments is a multi-arm robot capable of independently moving more than one wafer at a time. In some embodiments, the first transfer chamber 921 comprises more than one robotic wafer transfer mechanism. The robot 925 in first transfer chamber 921 is configured to move wafers between the chambers around the first transfer chamber 921. Individual wafers are carried upon a wafer transport blade that is located at a distal end of the first robotic mechanism.

After processing a wafer in the first section 920, the wafer can be passed to the second section 930 through a pass-through chamber. For example, pass through-chambers 922, 924 can be uni-directional or bi-directional pass-through chambers. The pass-through chambers 922, 924 can be used, for example, to cryo cool the wafer before processing in the second section 930, or allow wafer cooling or post-processing before moving back to the first section 920.

A system controller 990 is in communication with the first robot 925, second robot 935, first plurality of processing chambers 902, 904, 916, 918 and second plurality of processing chambers 906, 908, 910, 912, 914. The system controller 990 can be any suitable component that can control the processing chambers and robots. For example, the system controller 990 can be a computer including a central processing unit (CPU) 992, memory 994, inputs/outputs (I/O) 996, and support circuits 998. The controller 990 may control the cluster tool 900 directly, or via computers (or controllers) associated with particular process chamber and/or support system components.

The controller 990 may be one of any form of general-purpose computer processor that can be used in an industrial setting for controlling various chambers and sub-processors. The memory 994 or computer readable medium of the controller 990 may be one or more of readily available memory such as non-transitory memory (e.g., random access memory (RAM)), read only memory (ROM), floppy disk, hard disk, optical storage media (e.g., compact disc or digital video disc), flash drive, or any other form of digital storage, local or remote. The memory 994 can retain an instruction set that is operable by the processor (CPU 992) to control parameters and components of the cluster tool 900.

The support circuits 998 are coupled to the CPU 992 for supporting the processor in a conventional manner. These circuits include cache, power supplies, clock circuits, input/output circuitry and subsystems, and the like. One or more processes may be stored in the memory 994 as software routine that, when executed or invoked by the processor, causes the processor to control the operation of the cluster tool 900 or individual processing units in the manner described herein. The software routine may also be stored and/or executed by a second CPU (not shown) that is remotely located from the hardware being controlled by the CPU 992.

Some or all of the methods of the disclosure may also be performed in hardware. As such, the process may be implemented in software and executed using a computer system, in hardware as, e.g., an application specific integrated circuit or other type of hardware implementation, or as a combination of software and hardware. The software routine, when executed by the processor, transforms the general purpose computer into a specific purpose computer (controller) that controls the chamber operation such that the processes are performed.

In some embodiments, the controller 990 has one or more configurations to execute individual processes or sub-processes to perform the methods described herein, e.g., method 10. The controller 990 can be connected to and configured to operate intermediate components to perform the functions of the methods described herein. For example, the controller 990 can be connected to and configured to control a molecular layer deposition chamber.

Processes may generally be stored in the memory 994 of the system controller 990 as a software routine that, when executed by the processor, causes the process chamber to perform processes of the disclosure. The software routine may also be stored and/or executed by a second processor (not shown) that is remotely located from the hardware being controlled by the processor. The methods of the disclosure may also be performed in hardware. As such, the process may be implemented in software and executed using a computer system, in hardware as, e.g., an application specific integrated circuit or other type of hardware implementation, or as a combination of software and hardware. The software routine, when executed by the processor, transforms the general purpose computer into a specific purpose computer (controller) that controls the chamber operation such that the processes are performed.

Some embodiments of the disclosure are directed to non-transitory computer readable medium including instructions, that, when executed by a controller of a processing chamber, causes the processing chamber to perform one or more operations of the methods described herein, e.g., method 10.

Although the disclosure herein has been described with reference to particular embodiments, it is to be understood that these embodiments are merely illustrative of the principles and applications of the disclosure. It will be apparent to those skilled in the art that various modifications and variations can be made to the method and apparatus of the disclosure without departing from the spirit and scope of the disclosure. Thus, it is intended that the disclosure include modifications and variations that are within the scope of the appended claims and their equivalents.

What is claimed is:

1. A method of manufacturing a semiconductor device, the method comprising:
exposing a semiconductor substrate in a semiconductor processing chamber to a carbon-containing precursor selected from one of more of the following compounds 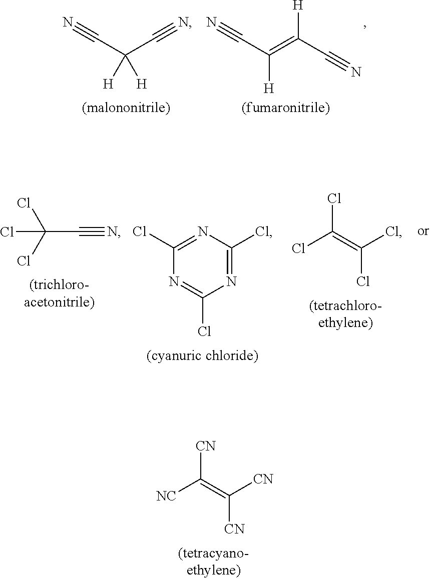
to deposit a carbon hardmask layer.

2. The method of claim 1, further comprising pre-treating the semiconductor substrate to prior to depositing the carbon hardmask layer.

3. The method of claim 2, wherein pre-treating the semiconductor substrate includes exposing the semiconductor substrate to a plasma comprising one or more of hydrogen (H₂), carbon monoxide (CO), carbon dioxide (CO₂), argon (Ar), helium (He), diborane (B₂H₆), nitrogen (N₂), ammonia (NH₃), or a gaseous hydrocarbon.

4. The method of claim 2, wherein pre-treating the semiconductor substrate includes depositing a seed layer directly on the semiconductor substrate.

5. The method of claim 1, wherein the carbon hardmask layer is deposited by a plasma-enhanced chemical vapor deposition (PECVD) process.

6. The method of claim 5, wherein the PECVD process is carried out with an inert gas.

7. The method of claim 6, wherein the PECVD process further comprises a plasma of one or more of hydrogen (H₂), carbon monoxide (CO), carbon dioxide (CO₂), diborane (B₂H₆), nitrogen (N₂), ammonia (NH₃), or a gaseous hydrocarbon.

8. The method of claim 1, wherein the carbon hardmask layer is deposited at a temperature in a range of from 100° C. to 500° C.

9. The method of claim 1, wherein the carbon hardmask layer is deposited at a pressure in a range of from 0.1 Torr to 20 Torr.

10. The method of claim 1, wherein the carbon hardmask layer is substantially free of hydrogen atoms.

11. The method of claim 1, further comprising treating the carbon hardmask layer.

12. The method of claim 11, wherein treating the carbon hardmask layer comprises exposing the carbon hardmask layer to a plasma comprising one or more of hydrogen (H₂), carbon monoxide (CO), carbon dioxide (CO₂), argon (Ar), helium (He), diborane (B₂H₆), nitrogen (N₂), ammonia (NH₃), or a gaseous hydrocarbon.

13. The method of claim 11, wherein treating the carbon hardmask layer comprises performing an annealing process.

14. The method of claim 1, wherein the semiconductor device is a logic device or a memory device.

15. A method of manufacturing a semiconductor device, the method comprising:
pre-treating a semiconductor substrate;
depositing a carbon hardmask layer that is substantially free of hydrogen atoms on the semiconductor substrate by plasma-enhanced chemical vapor deposition (PECVD), depositing the carbon hardmask layer comprising exposing the semiconductor substrate in a semiconductor processing chamber to a carbon-containing precursor selected from one of more of the following compounds 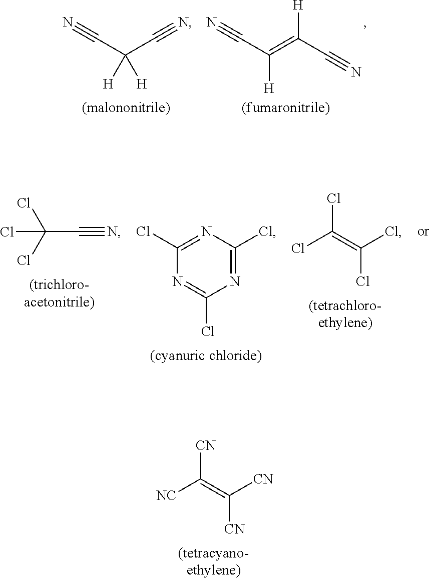
at a temperature in a range of from 100° C. to 500° C. and a pressure in a range of from 0.1 Torr to 20 Torr; and
treating the carbon hardmask layer.

16. The method of claim 15, wherein the PECVD process is carried out in an inert gas.

17. The method of claim 16, wherein the PECVD process further comprises a plasma of one or more of hydrogen (H₂), carbon monoxide (CO), carbon dioxide (CO₂), diborane (B₂H₆), nitrogen (N₂), ammonia (NH₃), or a gaseous hydrocarbon.

18. The method of claim 15, wherein treating the carbon hardmask layer comprises exposing the carbon hardmask layer to a plasma comprising one or more of hydrogen (H₂), carbon monoxide (CO), carbon dioxide (CO₂), argon (Ar), helium (He), diborane (B₂H₆), nitrogen (N₂), ammonia (NH₃), or a gaseous hydrocarbon.

19. The method of claim 15, wherein treating the carbon hardmask layer comprises performing an annealing process.

20. The method of claim 15, wherein the semiconductor device is a logic device or a memory device.
